(19) United States
(12) Patent Application Publication
(10) Pub. No.: US 2007/0080408 A1
(43) Pub. Date: Apr. 12, 2007

(54) Method for forming a silicidated contact

(75) Inventors: Philippe Absil, Loupoigne (BE); Jorge Adrian Kittl, Waterloo (BE)

Correspondence Address: MCDONNELL BOEHNEN HULBERT & BERGHOFF LLP, 300 S. WACKER DRIVE, 32ND FLOOR, CHICAGO, IL, 60606, US

(73) Assignees: Interuniversitair Microlektronica Centrum (IMEC), Leuven (BE); Texas Instruments Inc., Dallas, TX (US)

(21) Appl. No.: 11/246,516

(22) Filed: Oct. 7, 2005

(51) Int. Cl. H01L 29/78; H01L 21/8234

(52) U.S. Cl. 257/384; 438/592; 438/682; 257/412

(57) ABSTRACT

A method is described for forming an at least partially silicided contact. In one embodiment, a hardmask is deposited over a contact. A coating of sacrificial material is then provided on top of the hardmask. The sacrificial material coating is etched back until the top of the contact is exposed. The contact is then opened, the sacrificial material is removed, and a silicidation of the contact is performed.

### BACKGROUND

The present invention relates to the field of semiconductor process technology and devices. In particular, the present invention relates to semiconductor devices with contacts formed by a reaction between a metal and a semiconductor material.

In general, silicidation can be described as an anneal process resulting in the formation of a metal-semiconductor metal alloy (a silicide) to act as a contact in any semiconductor device, i.e. as a connection that permits a flow of current. The process can be applied for any contact located higher than the substrate surface. An example can be a layer stack of some semiconductor material.

A more specific example is found in CMOS (Complementary Metal-Oxide-Silicon) technology. CMOS devices comprise two types of transistors, nMOS and pMOS, each transistor type having its own characteristics and properties. There is a trend to replace the semiconductor gate contact with a metal one, as metal gates offer the advantages of reducing the sheet resistance, eliminating the semiconductor gate depletion effect, and controlling the work function independently from the doping of the junction regions. Metal gate contacts are therefore considered as a potential candidate for future CMOS technology nodes.

Metal gate contacts can be formed by a silicidation of the semiconductor gate contact with a metal. The semiconductor gate contact may be a poly-silicon gate contact. The metal may be a refractory metal such as W, noble metals such as Pt, near noble metals such as Ni, transition metals such as Ti, or any combination thereof. The full silicidation of the poly-Si gate is obtained by a thermally enhanced reaction between a deposited metal and the already patterned silicon gate similar to the process used to form self-aligned contacts in the source and drain (S/D) regions of a planar MOS transistor. During the silicidation process, the gate contact is converted into a gate silicide.

There are two main approaches to realise the (full or partially) silicided gates. In the first approach, a simultaneous silicidation of the source/drain (S/D) regions and the poly-Si gate contact is performed, trading off the needs for a thin contact in the S/D region imposed by the junctions requirements on the one hand and the silicidation of the full thickness of the poly-Si down to gate dielectric interface on the other hand. The second approach consists of decoupling the silicidation of the S/D regions and the gate by properly protecting the S/D regions during the silicide formation process (with a material that does not react with the metal). While the simultaneous approach is more economical in terms of number of process steps and minimises the thermal budget after contact formation, the decoupling approach allows the formation of a different silicide material for the gate contact and the S/D contacts and does not require silicide thickness matching between gate and S/D.

The main approach for decoupling S/D and gate contact consists in protecting the S/D by an oxide that is first deposited, then planarized by chemo-mechanical polishing (CMP) and then etched back to open the top of the poly-Si. Although this approach employs existing processing techniques, chip manufacturers preferably avoid it because of potential yield issues. Besides, this approach leaves a relative thick oxide above the S/D regions, difficult to remove without affecting the device integrity, specifically without damaging the S/D silicide underneath. With the protective oxide present, the efficiency of deposited strained layers, typically used for device performance improvement, will be significantly reduced. Another drawback of such approach is the increased risk of protective oxide removal when fully silicided gates are realised combined with elevated S/D transistors because of a process window difference for the etch back step used to open the gate top. This makes the approach partially incompatible with today's state-of-the-art transistors.

Also when considering the making of silicided contacts in general, it is desirable to avoid the CMP step because of the above-mentioned yield issues.

The present invention aims to provide a method for forming an at least partially silicided contact wherein a step of chemo-mechanical polishing is avoided.

### SUMMARY

The method described herein relates to the formation of an at least partially silicided contact. In one exemplary embodiment, a hardmask is deposited over a contact. A coating of sacrificial material is then provided on top of the hardmask. The sacrificial material coating is etched back until the top of the contact is exposed. The contact is then opened, the sacrificial material is removed, and a silicidation of the contact is performed.

In a preferred embodiment, the hardmask can be any material suitable to be deposited and dry-etched selectively to the contact. More particular it can be silicon oxide, silicon nitride or silicon carbide.

Preferably the sacrificial material coating can be any self-planarizing coating suitable to be spun on the hardmask and etched back afterwards. More particularly it can be BARC (bottom anti-reflective coating) or photo-resist.

Advantageously, a plurality of contacts can be formed. The step of etching back the sacrificial material coating can be performed until the lowest top of the plurality of contacts is exposed.

In a specifically advantageous embodiment the contact can be in CMOS technology. The hardmask can be then preferably be in SiO₂. The contact advantageously can be a poly-Si gate contact on top of a gate dielectricum. The gate dielectricum can be typically SiON, SiO or a high-k material. In a preferred embodiment, the step of hardmask deposition can be performed after a silicidation of a source and drain contact. Alternatively a silicidation of a source and drain contact can be performed after the silicidation of said gate contact.

In another embodiment, the method is used in forming a silicided contact wherein the contact is in CMOS technology, for forming a MOSFET transistor comprising a fully silicided gate contact.

In another aspect, the source contact and the drain contact of the MOSFET transistor can be in a first silicide material and wherein the fully silicided gate contact can be in a second silicide material, different from the first silicide material.

The methods described can be used to form a MOSFET transistor comprising a fully silicided gate contact.

### BRIEF DESCRIPTION OF THE DRAWINGS

FIG. 1 is a cross sectional view illustrating hard mask deposition.

FIG. 2 is a cross sectional view illustrating the planarizing polymer (PP) coating.

FIG. 3 is a cross sectional view illustrating the sacrificial etch back step to expose the contact tops.

FIG. 4 is a cross sectional view illustrating the contact opening.

FIG. 5 is a cross sectional view illustrating the removal of the sacrificial material.

FIG. 6 is a cross sectional view illustrating the silicidation metal deposition.

FIG. 7 is a cross sectional view illustrating the removal of the rest of the hardmask.

### DETAILED DESCRIPTION

In a preferred embodiment, an alternative to the CMP route is proposed. Doing so, any CMP step is avoided and a significant reduction of the protective oxide thickness can be achieved.

In this embodiment, a sacrificial protective layer is used during the contact opening process. The sacrificial layer can be removed prior to the contact silicidation without damaging the underlying layers.

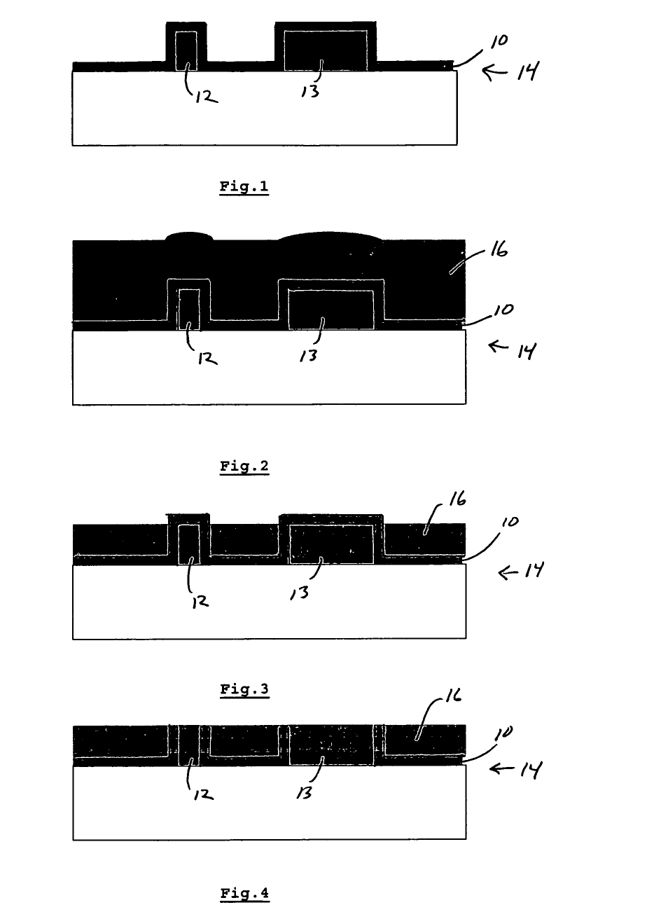

The process sequence is as follows: (i) a thin hardmask material 10 (FIG. 1), suitable for silicidation, is deposited over the contacts 12, 13 of a device 14. Any material that can be deposited and dry etched selectively to the contact and does not react with the silicide in question is suitable for silicidation. The hardmask thickness should preferably be about a few tens of nm. Examples comprise SiO₂, SiN, SiC or amorphous carbon layer. In case CMOS technology is used, the hardmask material is advantageously SiO₂. The hardmask is then preferably deposited on the encapsulated (by gate hardmask and spacers) transistors after S/D silicidation.

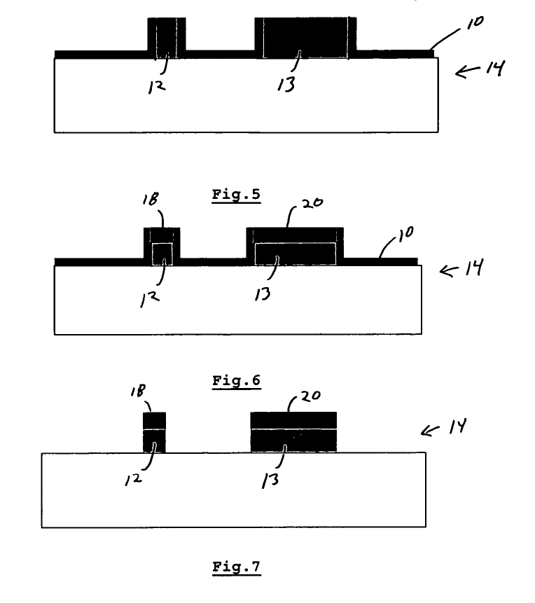

As illustrated in FIG. 2, the device 14 is spun coated with a sacrificial material 16, such as, for example, BARC, photo-resist or others, that planarizes the wafer topography. As illustrated in FIG. 3, the sacrificial material coating 16 is then etched back to expose the hardmask only on top of the contacts 12, 13. In an embodiment in which a plurality of contacts is formed, the second etchback may be performed until the lowest one of those contacts is exposed. Once the contact tops are exposed, a second etchback is performed to remove the hardmask 10 selectively to the sacrificial material coating (FIG. 4).

In case of gate contact silicidation, the gate hardmask is also removed selectively, while the S/D regions are protected by the sacrificial material. As shown in FIG. 5, the sacrificial material coating (16 in FIGS. 2-4) is removed without damaging the device structure. The contact is now ready to be at least partially silicided following known silicidation processes (FIG. 6), e.g., starting with a metal deposition, then a partial anneal, a selective etch and a final anneal to complete the contact silicidation to generate at least partial silicide regions 18 and 20. After silicidation is completed, the rest of the hard mask is removed selectively to the underlying layers and the contact (FIG. 7).

In a specific embodiment with CMOS technology the silicidation of the source and drain is performed after the above-mentioned steps for forming a silicided gate contact are carried out. After the silicidation process is completed, the transistors are ready to continue processing through BEOL (back-end-of-line).

It is important to note that prior to BEOL CMOS processing, it is possible to include a hardmask removal step to etch away protective layer present in the S/D regions, provided that this layer is thin enough and can be selectively etched with respect to the silicide formed in the gate and in the S/D.

This process according to the present invention avoids any CMP step and provides a topography very similar to the one obtained for standard poly-Si gates used in today's state-of-the-art CMOS fabrication. Both aspects make FUSI gates easier to integrate.

1. A method of forming an at least partially silicided contact, comprising the steps of:
depositing a hardmask over a contact;
providing a sacrificial material coating on top of said hardmask;
etching back said sacrificial material coating until the top of said contact is exposed;
opening said contact;
removing said sacrificial material; and
performing a silicidation of said contact.

2. The method of claim 1, wherein said hardmask is a material suitable to be deposited and dry-etched selectively to the contact.

3. The method of claim 1, wherein said hardmask is a material selected from the group consisting of silicon oxide, silicon nitride and silicon carbide.

4. The method of claim 1, wherein said sacrificial material coating is a self-planarizing coating suitable to be spun on the hardmask and etched back afterward.

5. The method of claim 1, wherein said sacrificial material coating is selected from the group consisting of a bottom anti-reflective coating and photo-resist.

6. The method of claim 1, wherein a plurality of contacts is formed.

7. The method of claim 6, wherein one of said plurality of contacts has a lowest top, and wherein said step of etching back said sacrificial material coating is performed until said lowest top of said plurality of contacts is exposed.

8. The method of claim 1, wherein said contact is a CMOS contact.

9. The method of claim 1, wherein said contact is CMOS technology and said hardmask is selected from the group consisting of silicon oxide, silicon nitride and silicon carbide.

10. The method of claim 1, wherein said contact is a poly-Si gate contact on top of a gate dielectricum.

11. The method of claim 10, wherein said gate dielectricum is a high-k material.

12. The method of claim 10, wherein said gate dielectricum is selected from the group consisting of SiON and SiO.

13. The method of claim 1, wherein the step of hardmask deposition is performed after a silicidation of a source and drain contact.

14. The method of claim 1, wherein said contact is a gate contact and wherein a silicidation of a source and drain contact is performed after the silicidation of said gate contact.

15. A method of forming a MOSFET transistor having a fully silicided gate stack, comprising:
depositing a hardmask over a contact;
providing a sacrificial material coating on top of said hardmask;
etching back said sacrificial material coating until the top of said contact is exposed;
opening said contact;
removing said sacrificial material; and
performing a silicidation of said contact.

16. The method of claim 15, wherein the source contact and the drain contact of said MOSFET transistor are in a first silicide material and wherein said fully silicided gate contact is in a second silicide material, different from said first silicide material.

17. A MOSFET transistor comprising a fully silicided gate stack obtained by:
depositing a hardmask over a contact;
providing a sacrificial material coating on top of said hardmask;
etching back said sacrificial material coating until the top of said contact is exposed;
opening said contact;
removing said sacrificial material; and
performing a silicidation of said contact.

18. The MOSFET transistor of claim 17, wherein the source contact and the drain contact of said MOSFET transistor are in a first silicide material and wherein said fully silicided gate contact is in a second silicide material, different from said first silicide material.
